(19) United States
(12) Patent Application Publication
(10) Pub. No.: US 2025/0280635 A1
(43) Pub. Date: Sep. 4, 2025

(54) SUBSTRATE, LIGHT-EMITTING DEVICE, METHOD OF MANUFACTURING SUBSTRATE, AND METHOD OF MANUFACTURING LIGHT-EMITTING DEVICE

(71) Applicant: NICHIA CORPORATION, Anan-shi (JP)

(72) Inventors: Hiroto KUME, Anan-shi (JP); Shoichi YAMADA, Anan-shi (JP)

(73) Assignee: NICHIA CORPORATION, Anan-shi (JP)

(21) Appl. No.: 19/041,870

(22) Filed: Jan. 30, 2025

(30) Foreign Application Priority Data
Feb. 29, 2024 (JP) 2024-030351

(51) Int. Cl. H10H 20/858; H10H 20/01

(52) U.S. Cl. CPC H10H 20/8581; H10H 20/0365

(57) ABSTRACT

A substrate includes a conductive member including first to third regions and a ceramic member. The first region contains copper and diamond. The second region contains copper as a main component. The third region is disposed between the first and second regions and the ceramic member, and contains copper and at least one selected from the group consisting of titanium, hafnium, zirconium, niobium, cerium, and magnesium. The diamond disposed in the first region in a vicinity of the third region is in contact with the third region. In a cross section, the first region includes a first portion and a second portion located between the first portion and the second region in a first direction, and an area occupied by diamond per unit area in the second portion is smaller than an area occupied by diamond per unit area in the first portion.

### CROSS-REFERENCE TO RELATED APPLICATIONS

The present application claims priority under 35 U.S.C. § 119 to Japanese Patent Application No. 2024-030351, filed Feb. 29, 2024, the contents of which is hereby incorporated by reference in its entirety.

### BACKGROUND

### 1. Technical Field

The present disclosure relates to a substrate, a light-emitting device, a method of manufacturing a substrate, and a method of manufacturing a light-emitting device.

### 2. Description of Related Art

There are substrates including a conductive member containing copper and a ceramic member. It is desirable that the difference in thermal expansion coefficient between the conductive member and the ceramic member of the substrate is small (for example, see Japanese Patent Publication No. 2008-004760.)

### SUMMARY

An embodiment of the present disclosure can advantageously provide a substrate in which a difference between thermal expansion coefficient of a conductive member and that of a ceramic member can be further reduced, and a light-emitting device including the substrate.

A substrate according to an embodiment includes a conductive member including a first region containing copper and diamond, a second region located on the first region and contains copper as a main component, and a third region; and a ceramic member disposed away from the first region and the second region in a second direction perpendicular to a first direction, the first direction being a direction from the first region toward the second region. The third region is located between the first region and the ceramic member and between the second region and the ceramic member, and contains copper and at least one selected from the group consisting of titanium, hafnium, zirconium, niobium, cerium, and magnesium. The diamond disposed in the first region in the vicinity of the third region is in contact with the third region. In a cross section parallel to the first direction, the first region comprises a first portion and a second portion that is located between the first portion and the second region in the first direction, and an area occupied by the diamond per unit area in the second portion is smaller than an area occupied by the diamond per unit area in the first portion.

A method of manufacturing a substrate according to an embodiment includes preparing a sintered body having a plurality of protrusions, by disposing a first raw material containing copper powder and diamond inside recesses of a jig having an upper surface and the recesses each recessed from the upper surface, disposing a second raw material containing copper powder on the first raw material and the upper surface of the jig, and sintering the first raw material and the second raw material; disposing, via an active metal brazing material, a ceramic member on a lateral surface of each of the plurality of protrusions of the sintered body removed from the jig; and bonding the ceramic member and the sintered body by sintering the active metal brazing material.

According to certain embodiments of the present disclosure, it is possible to provide a substrate in which a difference between thermal expansion coefficient of a conductive member and that of a ceramic member can be reduced, and a light-emitting device including the substrate.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1 is a cross-sectional view illustrating a substrate according to an embodiment.

FIG. 2 is a plan view illustrating the substrate according to the embodiment.

FIG. 3 is a bottom view illustrating the substrate according to the embodiment.

FIG. 4A is an enlarged cross-sectional view of the vicinity of a boundary between a first region and a third region.

FIG. 4B is a cross-sectional view illustrating an example of a diamond.

FIG. 4C is a cross-sectional view illustrating an example of a composite particle.

FIG. 4D is a cross-sectional view illustrating an example of a composite particle.

FIG. 5 is an enlarged cross-sectional view of the first region and a second region.

FIG. 6 is an enlarged cross-sectional view of a ceramic member.

FIG. 7 is a cross-sectional view illustrating a light-emitting device according to the embodiment.

FIG. 8A is a schematic view illustrating a step of manufacturing the substrate according to the embodiment.

FIG. 8B is a schematic view illustrating a step of manufacturing the substrate according to the embodiment.

FIG. 8C is a schematic view illustrating a step of manufacturing the substrate according to the embodiment.

FIG. 8D is a schematic view illustrating a step of manufacturing the substrate according to the embodiment.

FIG. 9A is a schematic view illustrating a step of manufacturing the substrate according to the embodiment.

FIG. 9B is a schematic view illustrating a step of manufacturing the substrate according to the embodiment.

FIG. 9C is a schematic view illustrating a step of manufacturing the substrate according to the embodiment.

FIG. 10A is a schematic view illustrating a step of manufacturing the substrate according to the embodiment.

FIG. 10B is a schematic view illustrating a step of manufacturing the substrate according to the embodiment.

FIG. 10C is a schematic view illustrating a step of manufacturing the substrate according to the embodiment.

FIG. 11A is a schematic view illustrating a step of manufacturing the substrate according to the embodiment.

FIG. 11B is a schematic view illustrating a step of manufacturing the substrate according to the embodiment.

FIG. 11C is a schematic view illustrating a step of manufacturing the substrate according to the embodiment.

FIG. 12A is a schematic view illustrating a step of manufacturing the light-emitting device according to the embodiment.

FIG. 12B is a schematic view illustrating a step of manufacturing the light-emitting device according to the embodiment.

FIG. 12C is a schematic view illustrating a step of manufacturing the light-emitting device according to the embodiment.

FIG. 12D is a schematic view illustrating a step of manufacturing the light-emitting device according to the embodiment.

FIG. 13A is a cross-sectional view illustrating a substrate according to a variation of the embodiment.

FIG. 13B is a cross-sectional view illustrating a substrate according to a variation of the embodiment.

FIG. 13C is a cross-sectional view illustrating a substrate according to a variation of the embodiment.

### DETAILED DESCRIPTION

### Description of Embodiments

Each embodiment of the present disclosure will be described below with reference to the drawings. The drawings are schematic or conceptual, and the relationships between thicknesses and widths of portions, the ratios of sizes between portions, and the like are not necessarily the same as the actual values thereof. In addition, even in the case of representing the same portion, dimensions or ratios may be represented differently depending on the drawings. In the present specification and the drawings, the same elements as those already described are denoted by the same reference numerals, and detailed description thereof will be omitted as appropriate. As a cross-sectional view, an end view illustrating only a cut surface may be used.

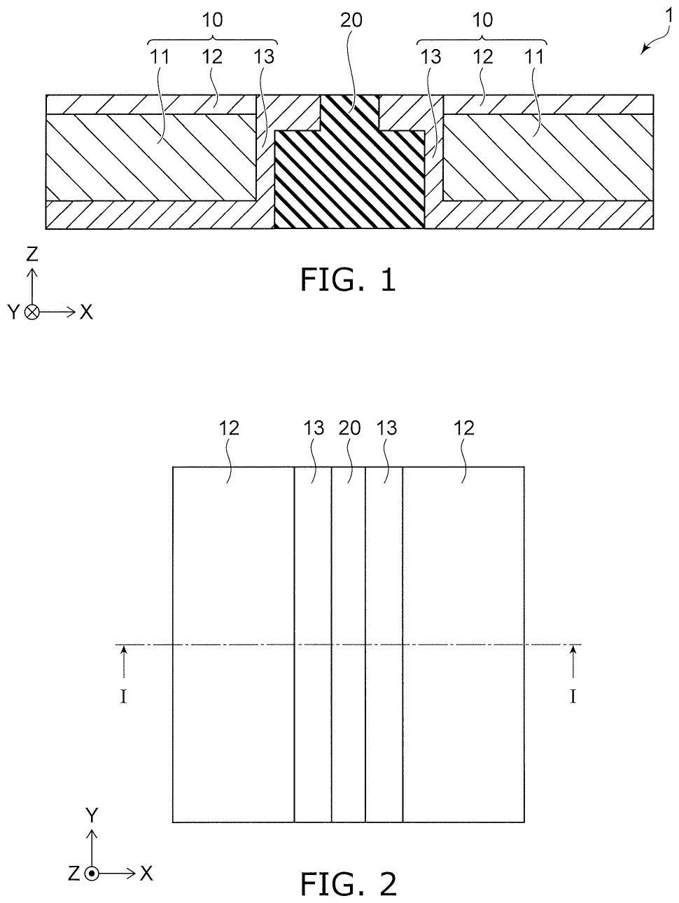

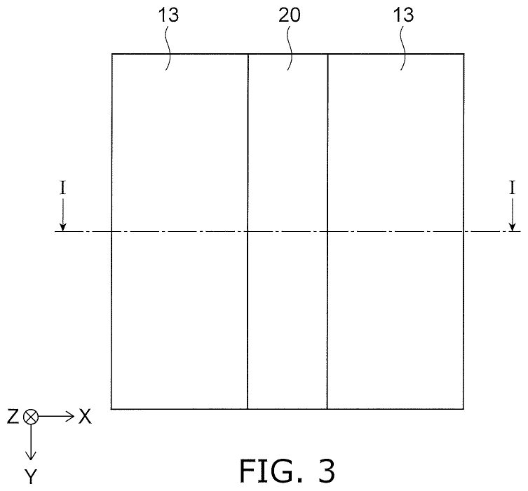

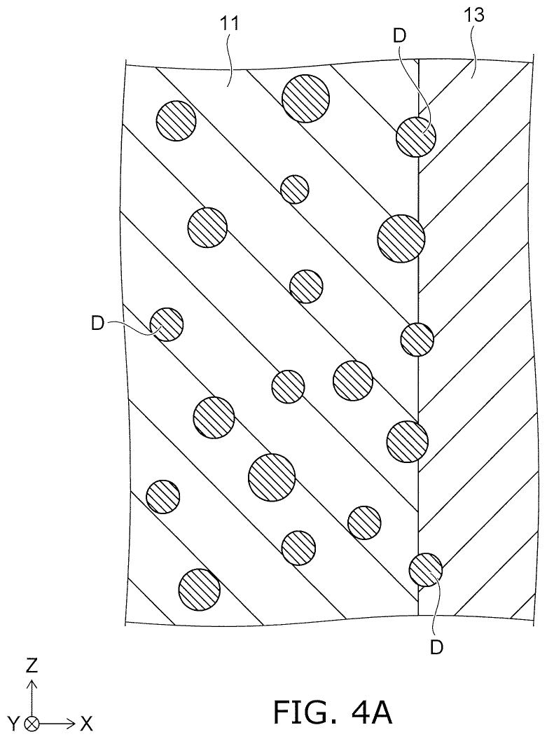

FIG. 1 is a cross-sectional view illustrating a substrate according to an embodiment. FIG. 2 is a plan view illustrating the substrate according to the embodiment. FIG. 3 is a bottom view illustrating the substrate according to the embodiment. FIG. 1 corresponds to a cross-sectional view taken along line I-I in FIGS. 2 and 3.

As illustrated in FIGS. 1 to 3, a substrate 1 according to the embodiment includes at least one conductive member 10 and a ceramic member 20. As illustrated in FIG. 1, each of the at least one conductive member 10 includes a first region 11, a second region 12, and a third region 13.

In the following description, an XYZ orthogonal coordinate system is used. A direction from the first region 11 toward the second region 12 is referred to as a Z direction (first direction). Two directions perpendicular to the Z direction and orthogonal to each other are referred to as an X direction (second direction) and a Y direction. For the sake of description, the direction from the first region 11 toward the second region 12 is referred to as “upward”, and the opposite direction is referred to as “downward”. These directions are based on the relative positional relationship between the first region 11 and the second region 12, and are irrelevant to the direction of gravity. The expression “in a plan view” as used in the embodiment refers to viewing the object from above. In the present specification, not only a portion that is directly visible from above, but also a portion that is not directly visible from above may be described as if it is seen through using the expression “in a plan view”.

The first region 11 contains copper and diamond. The second region 12 is disposed above the first region 11. The second region 12 contains copper as a main component. The term “main component” refers to a component contained in an amount of 50% or more.

The ceramic member 20 is disposed away from the first region 11 and the second region 12 in the X direction. The ceramic member 20 has insulating properties. The ceramic member 20 can be, for example, a sintered body of silicon nitride, aluminum nitride, aluminum oxide, zirconium oxide, or the like.

The third region 13 is disposed between the first region 11 and the ceramic member 20 and between the second region 12 and the ceramic member 20 in the X direction. The third region 13 is in contact with the first region 11, the second region 12, and the ceramic member 20. Therefore, in the example illustrated in FIG. 1, the conductive member 10 and the ceramic member 20 are in contact with each other. As illustrated in FIG. 1, the third region 13 is further located below the first region 11. The third region 13 is further located above a portion of the ceramic member 20.

The third region 13 contains copper and at least one selected from the group consisting of titanium, hafnium, zirconium, niobium, cerium, and magnesium. Titanium, hafnium, zirconium, niobium, cerium, and magnesium are so-called active metals. The third region 13 contains copper as a main component and contains an active metal. The third region 13 can further contain silver. When the third region 13 contains silver, the boundary between the first region 11 and the third region 13 is more easily recognized. The third region 13 can further contain tin, indium, or the like.

As illustrated in FIGS. 1 and 2, the second region 12, the third region 13, and the ceramic member 20 are exposed on the upper surface of the substrate 1. As illustrated in FIGS. 1 and 3, the third region 13 and the ceramic member 20 are exposed on the lower surface of the substrate 1.

As illustrated in FIG. 1, the thickness of the first region 11 in the Z direction is greater than the thickness of the second region 12 in the Z direction. With this structure, the proportion of the first region 11 in the conductive member 10 can be higher than the proportion of the second region 12 in the conductive member 10, so that the thermal expansion coefficient of the conductive member 10 can be further reduced. More preferably, the thickness of the first region 11 in the Z direction is not less than 1.5 times and not more than 50 times the thickness of the second region 12 in the Z direction.

The dimensional relationship between the first region 11, the second region 12, and the ceramic member 20 can be appropriately designed. In one example, the length of the first region 11 in the X direction and the length of the second region 12 in the X direction are greater than the length of the ceramic member 20 in the X direction. This structure allows for improving the heat dissipation of the substrate 1.

In the example illustrated in FIGS. 1 to 3, the substrate 1 includes a plurality of conductive members 10. The ceramic member 20 is disposed between two conductive members 10 in the X direction. Specifically, one ceramic member 20 having a rectangular shape in a plan view is located between two conductive members 10 having a rectangular shape in a plan view, and the conductive members 10 and the ceramic member 20 are disposed adjacent to each other.

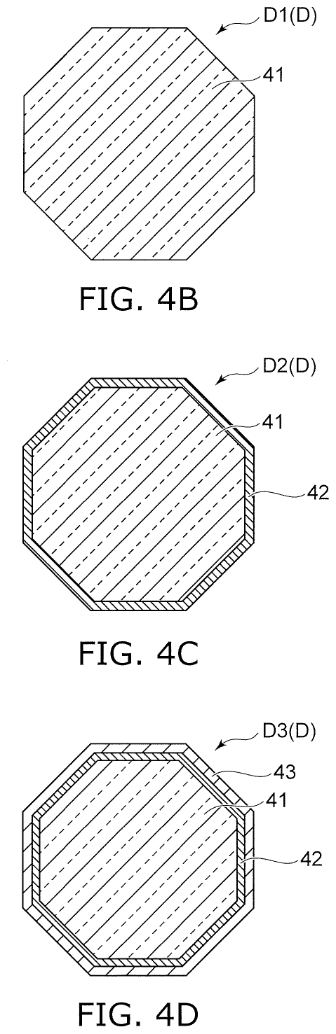

FIG. 4A is an enlarged cross-sectional view of the vicinity of a boundary between the first region and the third region. FIG. 4B is a cross-sectional view illustrating an example of a diamond. FIG. 4C is a cross-sectional view illustrating an example of a composite particle. FIG. 4D is a cross-sectional view illustrating an example of a composite particle.

In the first region 11, particulate diamond D is dispersed in a base material containing copper as a main component. As illustrated in FIG. 4A, the diamond D in the first region 11 disposed in the vicinity of the third region 13 is in contact with the third region 13.

The diamond D that is used in the present embodiment can be an artificially produced industrial diamond. The diamond D has a higher hardness and a lower thermal expansion coefficient than those of a metal used for the substrate. Therefore, with the diamond D disposed in the conductive member 10, it is possible to reduce the occurrence of shrinkage, cracks, and the like of the conductive member 10 due to heat. In addition, because the diamond D has a thermal conductivity higher than that of metals and has isotropy in a thermal conduction direction, disposing the diamond D in the conductive member 10 allows for improving the heat dissipation of the substrate 1. The shape of the diamond D is, for example, a sphere or a polyhedron, and can be a polyhedron close to a sphere.

The configuration of the diamond D will be described below. Each of FIGS. 4B to 4D is a cross-sectional view illustrating an example of the diamond D. In the example illustrated in FIG. 4B, the diamond DI is a diamond particle 41. The shape of the diamond particle 41 is, for example, a polyhedron having a cleavage plane. The diamond D can be a composite particle having a diamond particle 41 and a plating layer covering the diamond particle 41. For example, as illustrated in FIG. 4C, the diamond D can be a composite particle D2 having a diamond particle 41 and a nickel-plating layer 42 covering the diamond particle 41. Meanwhile, as illustrated in FIG. 4D, the diamond D can be a composite particle D3 having a diamond particle 41, a nickel-plating layer 42 covering the diamond particle 41, and a copper plating layer 43 covering the nickel-plating layer. In particular, when the composite particle contains a diamond particle, good thermal conductivity can be obtained. In addition, with the diamond particle 41 covered with a metal film such as a plating layer, adhesion between the diamond D and the metal contained in the conductive member 10 is improved. In the present embodiment, the diamond D1 composed of the diamond particle 41, the composite particle D2, and the composite particle D3 are collectively referred to as “diamond D”.

The particle size of each diamond D contained in the first region 11 is 20 μm or greater and 130 μm or less. The term “particle size” as used herein refers to the diameter of the smallest sphere that circumscribes the diamond D. The diamond D has any appropriate shape and has, for example, a hexahedron shape or an octahedron shape. If the particle size of the diamond D is less than 20 μm, the thermal conductivity of the diamond D is low, which may result in reduction in the thermal conductivity of the first region 11. If the particle size of the diamond D exceeds 130 μm, the area of the diamond D in contact with the third region 13 is small in the vicinity of the boundary between the first region 11 and the third region 13 when the density of the diamond D is constant. That is, by setting the particle size of the diamond D to 20 μm or greater and 130 μm or less, the area of copper in the first region 11 is reduced in the vicinity of the boundary between the first region 11 and the third region 13. Therefore, the amount of voids generated due to the dissolution of copper from the first region 11 to the third region 13 can be reduced. Thus, the particle size of the diamond D is preferably 20 μm or greater and 130 μm or less, more preferably greater than 20 μm and 80 μm or less.

The particle size of the diamond D is determined by image analysis of an observation photograph of a cross section, sorting using a sieve, or the like. For example, in scanning electron microscopy-energy dispersive X-ray spectroscopy (SEM-EDX; hereinafter occasionally referred to as “EDX”), diamond particles 41 are observed to be darker than copper. The particle size of the diamond D can be obtained by extracting a black region from the image and measuring the size of the region. Alternatively, the diamond D can be taken out by cutting out the first region 11 from the conductive member 10 and dissolving copper contained in the first region 11 with an acidic solution. The particle size of the taken-out diamond D is observed by, for example, observing the diamond D using an optical microscope, SEM (scanning electron microscopy), or SEM-EDX and measuring the size of the diamond D. The taken-out diamond D can be sieved with a mesh. The diamond D is sequentially sieved from a finer mesh to a coarser mesh. The particle size of the diamond D can be estimated from the size of the mesh when the diamond D passes through the mesh.

Any appropriate content of the diamond D can be contained in the first region 11. Preferably, in a cross section parallel to the Z direction, the diamond D occupies 10% or more and 50% or less of the area of the first region 11. When the area occupied by the diamond D in the cross section is less than 10%, the effect of reducing the thermal expansion coefficient of the first region 11 by the diamond D may be insufficient. When the area occupied by the diamond D exceeds 50%, the conductivity of the first region 11 may be reduced by the diamond D. Therefore, the area occupied by the diamond D in the cross section is preferably 10% or more and 50% or less, more preferably 25% or more and 45% or less, of the area of the first region 11.

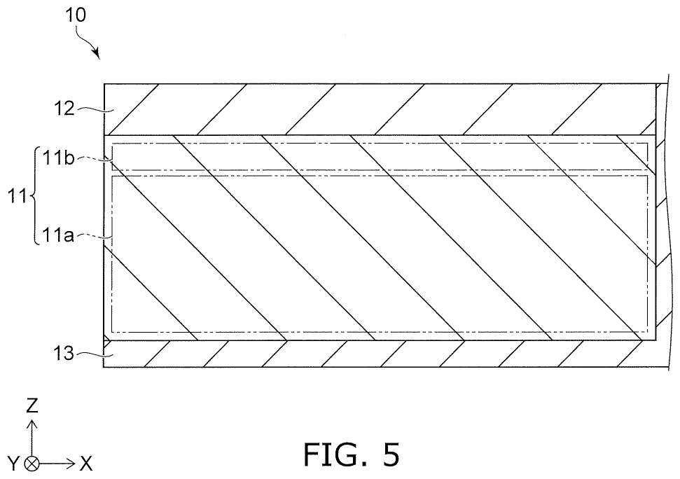

FIG. 5 is an enlarged cross-sectional view of the first region and the second region illustrated in FIG. 1.

As illustrated in FIG. 5, the first region 11 includes a first portion 11a and a second portion 11b. The second portion 11b is positioned between the first portion 11a and the second region 12 in the Z direction. When a cross section of the conductive member 10 parallel to the Z direction is observed, the area occupied by the diamond D per unit area in the second portion 11b is smaller than the area occupied by the diamond D per unit area in the first portion 11a.

When it is confirmed from the observation result of the cross section that the area occupied by the diamond D per unit area in the second portion 11b is smaller than the area occupied by the diamond D per unit area in the first portion 11a, it is estimated that the volume occupied by the diamond D per unit volume in the second portion 11b is smaller than the volume occupied by the diamond D per unit volume in the first portion 11a in the first region 11 of the conductive member 10. When the diamond D is a composite particle having a plating layer on the surface thereof, the thickness of the plating layer is very small relative to the volume of the diamond particle 41, and thus the thickness of the plating layer is ignored.

In the first region 11, the portion other than the diamond D is mainly made of copper. Therefore, when the area occupied by the diamond D per unit area in the second portion 11b is smaller than the area occupied by the diamond D per unit area in the first portion 11a, the area occupied by copper per unit area in the second portion 11b is larger than the area occupied by copper per unit area in the first portion 11a. In addition, when it is confirmed from the observation result of the cross section that the area occupied by copper per unit area in the second portion 11b is larger than the area occupied by copper per unit area in the first portion 11a, it is estimated that the volume occupied by copper per unit volume in the second portion 11b is larger than the volume occupied by copper per unit volume in the first portion 11a in the first region 11 of the conductive member 10.

In the present embodiment, a difference in density of the diamond D between the first portion 11a and the second portion 11b is present. With such a portion with a low density of the diamond D, such as the second portion 11b, between the first portion 11a and the second region 12 in this way, it is possible to inhibit entry of the diamond D into the second region 12. Inhibiting entry of the diamond D into the second region 12 allows for inhibiting the upper surface of the second region 12 from becoming uneven, and thus improving the accuracy of arrangement when arranging a light-emitting element 33 on the second region 12 as will be described below.

There can be a case in which the first region 11, the second region 12, and the third region 13 in the present embodiment does not have a clear boundary line that allows such regions to be visually distinguished. In this case, the first region 11, the second region 12, and the third region 13 are distinguished as follows.

In one example, in the cross section of the conductive member 10, the first region 11 and the second region 12 are distinguished by the presence of the diamond D. That is, when the cross section of the conductive member 10 is observed, a region where the diamond D is present is determined as the first region 11. A region located on the first region 11 and having no diamond D is determined as the second region 12. In addition, in the cross section of the conductive member 10, the first region 11 and the third region 13 are also distinguished by the presence or absence of the diamond D. That is, when the cross section of the conductive member 10 is observed, a region where the diamond D is present is determined as the first region 11. A region located on the X-direction side with respect to the first region 11 and having no diamond D is determined as the third region 13. Furthermore, the first region 11 and the third region 13 can be distinguished on the basis of the concentration of the active metal.

For example, SEM-EDX is used to observe the cross-section of the conductive member 10. First, the substrate 1 is cut along the Z direction so as to include the first region 11 and the second region of the conductive member 10. The cut surface of the substrate 1 is polished, and the polished surface is observed through SEM.

To distinguish the first region 11 and the second region 12 from each other, the diamond D is confirmed in the image obtained through SEM. In SEM, the heavier element a portion contains, the whiter the portion is observed to be. When the copper element is compared with the carbon element contained in diamond, the copper element is heavier. Therefore, in the result of observation through SEM, diamond is observed to be black as compared with copper. The first region 11 and the second region 12 are distinguished on the basis of the presence of a black region corresponding to diamond.

To distinguish the first region 11 and the third region 13 from each other, a rough boundary between the first region 11 and the third region 13 is grasped on the basis of the distribution of the diamond D in the X direction. The vicinity of the boundary is observed, and elemental mapping of the active metal is obtained through EDX. In the vicinity of the boundary between the first region 11 and the third region 13, a change in the concentration of the active metal in the X direction is present. The first region 11 and the third region 13 are distinguished from each other on the basis of the concentration of the active metal acquired by the elemental mapping. In the first region 11, an EDX spectrum of the active metal is not observed, and the active metal is not detected.

In the substrate 1 according to the embodiment, when the first region 11 and the third region 13 are distinguished by the above-described method, the diamond D in the first region 11 in the vicinity of the third region 13 is in contact with the third region 13. That is, a portion of the diamond D is in contact with a region where an EDX spectrum of the active metal is observed.

In addition, the first portion 11a and the second portion 11b are distinguished on the basis of the area occupied by diamond or copper in the first region 11. As described above, when the first region 11 is observed through SEM, copper and diamond have different colors. By image analysis of the observation photograph, the area of the white portion is measured as the area of copper, and the area of the black portion is measured as the area of diamond. In the first region 11, a plurality of sections are set in the Z direction, and an area occupied by each of copper and diamond per unit area is calculated for each section. A section where the area occupied by diamond per unit area is relatively large is distinguished as the first portion 11a. A section where the area occupied by diamond per unit area is relatively small is distinguished as the second portion 11b.

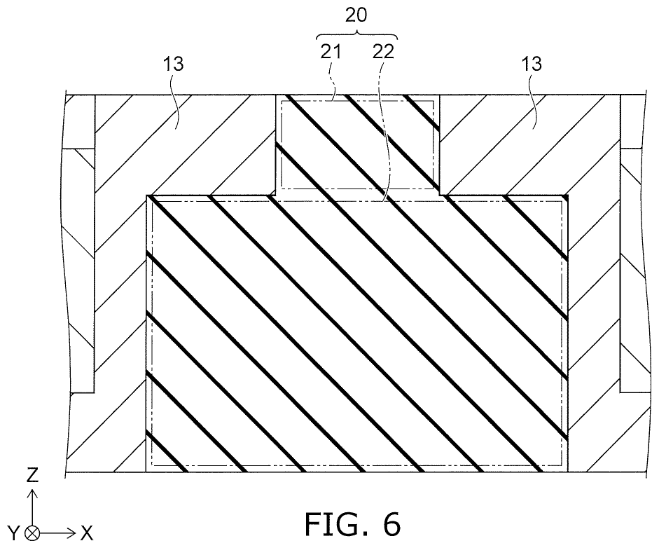

FIG. 6 is an enlarged cross-sectional view of the ceramic member illustrated in FIG. 1. For example, as illustrated in FIG. 6, the width (the length in the X direction) of an upper portion 21 of the ceramic member 20 is smaller than the width (the length in the X direction) of a lower portion 22 of the ceramic member 20. The third region 13 is disposed on the lower portion 22 in a portion other than the upper portion 21. The thickness (the length in the Z direction) of the upper portion 21 is smaller than the thickness (the length in the Z direction) of the lower portion 22. In this case, the third region 13 can be disposed on the lower portion 22 in a portion other than the upper portion 21. The proportion of the third region 13 on the upper surface of the substrate 1 can be further increased. The third region 13 contains a metal, and thus the thermal conductivity of the third region 13 is higher than the thermal conductivity of the ceramic member 20. Therefore, the heat dissipation of the substrate 1 can be further enhanced. However, the specific shape of the ceramic member 20 is not limited to the above.

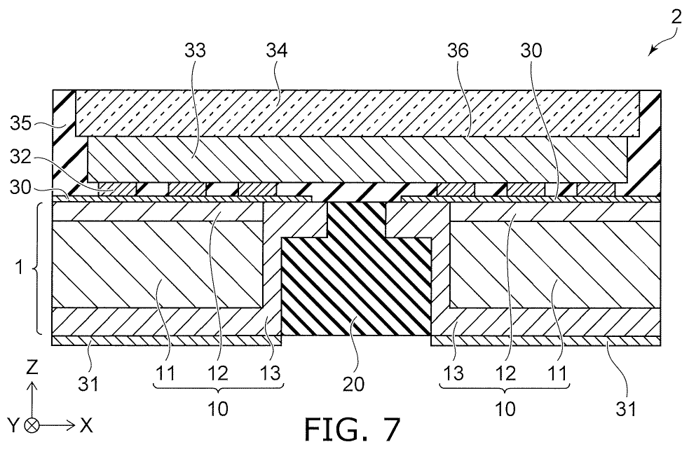

FIG. 7 is a cross-sectional view illustrating a light-emitting device according to the embodiment. The substrate 1 according to the embodiment is suitably used for a light-emitting device. As illustrated in FIG. 7, a light-emitting device 2 includes a substrate 1, a metal layer 30, a metal layer 31, a bonding member 32, a light-emitting element 33, a phosphor member 34, and a covering member 35.

The metal layer 30 is disposed on the upper surface of the second region 12 and the upper surface of the third region 13. The metal layer 31 is disposed on the lower surface of the third region 13. The metal layers 30 and 31 include a thin film of nickel, palladium, gold, or the like.

The bonding member 32 is disposed on the metal layer 30. In the example illustrated in FIG. 7, the bonding members 32 are disposed at a plurality of locations to bond the substrate 1 and the light-emitting element 33. The bonding member 32 is, for example, solder. Since the metal layer 30 is disposed on the upper surface of the ceramic member 20, wettability for the bonding member 32 is improved.

In the example illustrated in FIG. 7, one light-emitting device 2 includes one light-emitting element 33. A light-emitting surface 36 is provided on the upper surface of the light-emitting element 33. At least a pair of positive and negative element electrodes are provided on a surface of the light-emitting element 33 opposite the light-emitting surface 36. In the example illustrated in FIG. 7, the shape of the light-emitting surface 36 in a plan view is substantially rectangular. However, the shape of the light-emitting surface 36 in a plan view can be substantially circular or substantially elliptical, and can be polygonal such as substantially triangular or substantially hexagonal. The number of light-emitting elements 33 included in one light-emitting device 2 can be two or more.

In the example illustrated in FIG. 7, the light-emitting element 33 is disposed on the second region 12 and the ceramic member 20, and is electrically connected to the second region 12. The light-emitting element 33 is bonded to the conductive member 10 via the element electrodes, the metal layer 30, and the bonding member 32. The light-emitting element 33 has various semiconductors such as a group III-V compound semiconductor or a group II-VI compound semiconductor. The light-emitting element 33 can be a light-emitting diode (LED), or can be a laser diode (LD). As the semiconductor, preferably, a nitride-based semiconductor such as In_{X}Al_{Y}Ga_{1-X-Y}N (0≤X, 0≤Y, X+Y≤1) or the like is used, and InN, AlN, GaN, InGaN, AlGaN, InGaAlN, and the like can also be used. The light-emitting element 33 includes an n-type semiconductor layer, a p-type semiconductor layer, and a light-emitting layer disposed between the n-type semiconductor layer and the p-type semiconductor layer. The p-type semiconductor layer of the light-emitting element 33 is electrically connected to one of the two conductive members 10, and the n-type semiconductor layer of the light-emitting element 33 is electrically connected to the other of the two conductive members 10. A light emission peak wavelength of the light-emitting element 33 is preferably 400 nm or greater and 530 nm or less, more preferably 400 nm or greater and 490 nm or less, and even more preferably 440 nm or greater and 475 nm or less, from the viewpoints of light emission efficiency, excitation of the phosphor to be described below, a color mixing relationship with the light emission thereof, and the like.

The phosphor member 34 is a member having a substantially rectangular shape in a plan view, for example, and is provided so as to cover the upper surface of the light-emitting element 33. The phosphor member 34 can be formed using a light-transmissive resin material, or an inorganic material such as ceramic or glass. As the resin material, a thermosetting resin, such as a silicone resin, a silicone modified resin, an epoxy resin, an epoxy modified resin, or a phenol resin, can be used. Particularly, a silicone resin or a modified resin thereof with good light resistance and heat resistance is preferably used. Herein, light transmissivity corresponds to preferably 60% or more of the light from the light-emitting element 33 being transmitted. Further, a thermoplastic resin such as a polycarbonate resin, an acrylic resin, a methyl pentene resin, or a polynorbornene resin can be used as the phosphor member 34. Furthermore, the phosphor member 34 contains a light diffusion substance or a phosphor that converts the wavelength of at least a portion of light from the light-emitting element 33. For example, the phosphor member 34 can be a resin material, ceramic, glass, or the like containing a phosphor, a sintered body of a phosphor, or the like. Further, the phosphor member 34 can be a multi-layer member in which a resin layer containing a phosphor and a light diffusion substance is disposed on the upper surface or the lower surface of a molded body formed of resin, ceramic, glass, or the like.

As the phosphor, an yttrium aluminum garnet-based phosphor (for example, (Y,Gd)₃(Al,Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor β-SiAlON-based phosphor (for example, (Si,Al)₃(O,N)₄:Eu) or an α-SiAlON-based phosphor (for example, Ca(Si,Al)₁₂(O,N)₁₆:Eu), a nitride-based phosphor such as an LSN-based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), or an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a group II-VI quantum dot (for example, CdSe), a group III-V quantum dot (for example, InP), a quantum dot having a chalcopyrite structure (for example, (Ag,Cu)(In,Ga)(S,Se)₂), or the like can be used.

In the example illustrated in FIG. 7, the light-emitting element 33 emits blue light, and the phosphor member 34 includes a phosphor that absorbs blue light and emits red light and a phosphor that absorbs blue light and emits green light. Alternatively, the phosphor member 34 can include a phosphor that absorbs blue light and emits yellow light.

The covering member 35 is disposed so as to cover the lateral surface of the light-emitting element 33 and the lateral surface of the phosphor member 34. The covering member 35 covers the lateral surfaces of the light-emitting element 33 and the phosphor member 34 directly or indirectly. The upper surface of the phosphor member 34 is exposed from the covering member 35 and corresponds to the light-emitting surface of the light-emitting device 2. The covering member 35 is further disposed between the metal layer 30 and the light-emitting element 33 and between the ceramic member 20 and the light-emitting element 33. The covering member 35 reflects light emitted toward the covering member 35 from the light-emitting element 33. The covering member 35 is integrally formed of, for example, a white resin material. The covering member 35 is preferably constituted by a member having a high light reflectivity in order to improve light extraction efficiency. As the covering member 35, an organic material such as a resin containing a light-reflective material such as white pigment, for example, can be used. Alternatively, the covering member 35 can be a light-reflective member composed of an inorganic material containing boron nitride and alkali metal silicate, for example. In this case, titanium oxide or zirconium oxide can be further contained.

Examples of the light reflective material include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, and silicon oxide. One type of these can be used alone, or two or more types of these can be used in combination. The resin material as the organic material is preferably a material in which a resin material including, as a main component, a thermosetting resin, such as an epoxy resin, an epoxy modified resin, a silicone resin, a silicone modified resin, a phenol resin, or the like is used as a base material. The covering member 35 can be constituted by a member having light transmissivity or absorbency for visible light as necessary.

When the light-emitting device 2 includes a plurality of light-emitting elements 33 and phosphor members 34 disposed on the light-emitting elements 33, the covering member 35 can be disposed between the adjacent light-emitting elements 33 and between the adjacent phosphor members 34 to integrally cover the plurality of light-emitting elements 33 and the plurality of phosphor members 34.

Advantages that can be provided by the embodiment of the present disclosure will be described below.

When light is emitted from the light-emitting device 2, heat is generated in the light-emitting element 33. The heat of the light-emitting element 33 is transmitted to the conductive member 10, the ceramic member 20, and the like. The temperatures of the conductive member 10, the ceramic member 20, and the light-emitting element 33 change depending on whether or not heat is generated by the light-emitting element 33. When the temperature changes, thermal expansion or thermal contraction occurs in each of the conductive member 10, the ceramic member 20, and the light-emitting element 33.

In the present embodiment, the first region 11 is provided in the conductive member 10. The first region 11 contains copper and diamond. The thermal expansion coefficient of the first region 11 containing copper and diamond is smaller than the thermal expansion coefficient of the second region 12 not containing diamond. With the conductive member 10 including the first region 11, the thermal expansion amount and the thermal contraction amount of the conductive member 10 can be reduced. Accordingly, stress generated between the conductive member 10 and the ceramic member 20 and stress generated between the conductive member 10 and the light-emitting element 33 during thermal expansion or thermal contraction can be reduced. As a result, the occurrence of breakage of the light-emitting element 33, malfunction of the light-emitting device 2, and the like due to temperature rise can be reduced.

According to the present embodiment, the substrate 1 including the conductive member 10 in which a difference in thermal expansion coefficient from the ceramic member 20 or the light-emitting element 33 can be provided. In addition, by using the substrate 1 according to the embodiment in the light-emitting device 2, the light-emitting device 2 having high reliability with respect to temperature changes can be provided.

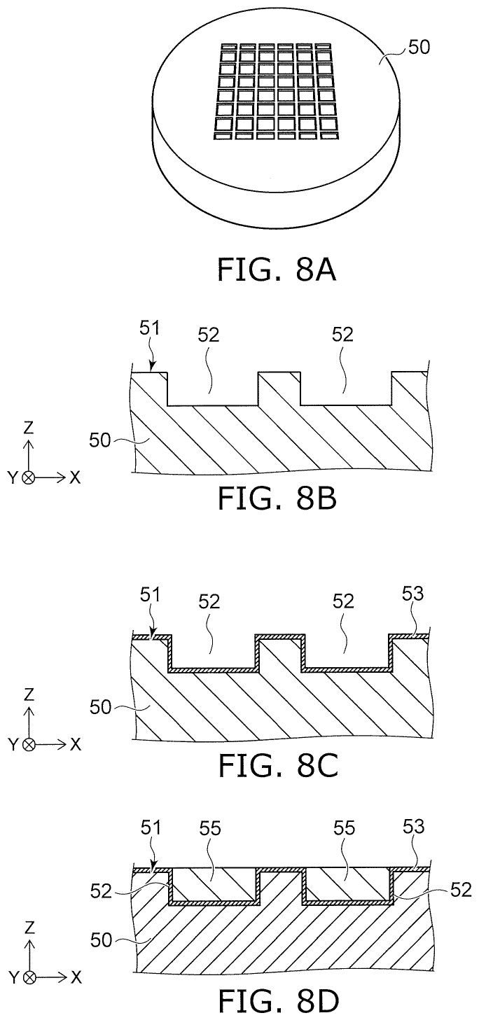

FIGS. 8A to 11C are each a schematic view illustrating a step of manufacturing the substrate according to the embodiment.

The steps of manufacturing the substrate according to the embodiment includes a step of providing a sintered body having a plurality of protrusions, a step of disposing a ceramic member, and a step of bonding the ceramic member and the sintered body.

First, the step of providing a sintered body having a plurality of protrusions will be described. In the step of providing a sintered body having a plurality of protrusions, a first raw material 55 containing copper powder and diamond is disposed inside recesses 52 of a jig 50 having an upper surface 51 and the recesses 52 recessed from the upper surface 51. A second raw material 57 containing copper powder is disposed on the first raw material 55 and the upper surface 51 of the jig 50, and the first raw material 55 and the second raw material 57 are sintered.

The jig 50 illustrated in FIG. 8A is used to manufacture the substrate 1. FIG. 8B is an enlarged cross-sectional view of a part of the jig 50. As illustrated in FIG. 8B, the jig 50 is a member having the upper surface 51 and the recesses 52 recessed from the upper surface 51.

As illustrated in FIG. 8C, a mold release material 53 is applied by spraying to the upper surface 51 and the inner surface of each of the recesses 52 of the prepared jig 50. The mold release material 53 contains carbon powder or boron nitride powder. As illustrated in FIG. 8D, the first raw material 55 is disposed inside each of the recesses 52. The first raw material 55 contains, for example, 60 wt % or more and 85 wt % or less of copper powder and 15 wt % or more and 40 wt % or less of the diamond D. The particle size of the diamond D is 20 μm or greater and 130 μm or less. It is preferable that the first raw material 55 is disposed such that almost no gap inside the recess 52 is present. Then, the upper surface of the mold release material 53 disposed on the upper surface 51 of the jig 50 is made flush with the upper surface of the first raw material 55 disposed inside the recess 52.

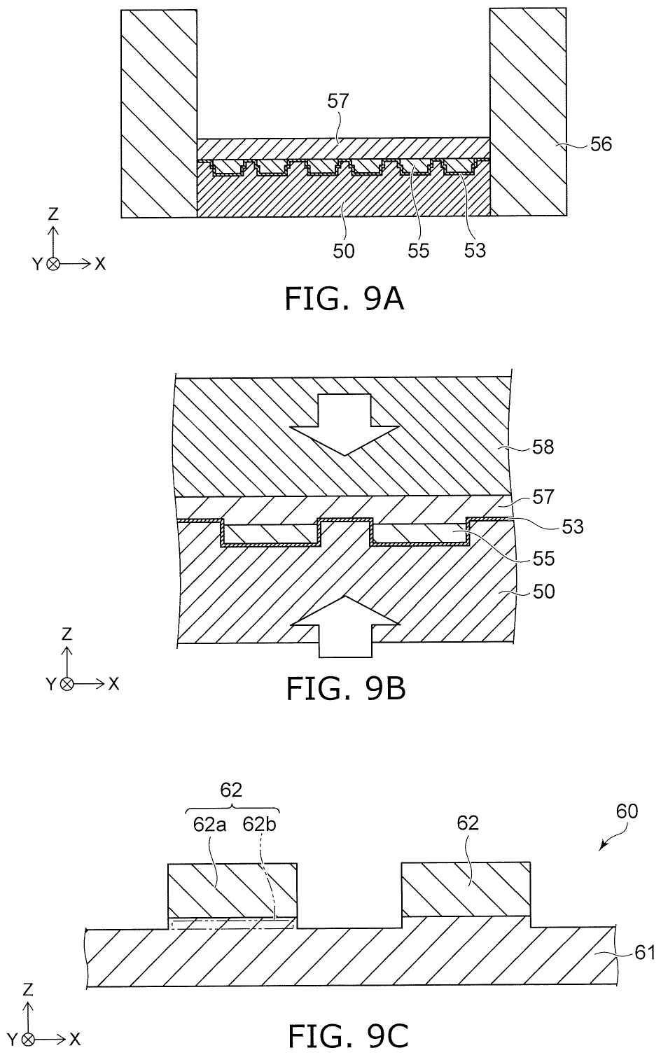

As illustrated in FIG. 9A, the jig 50 is disposed inside a tubular body 56, and the second raw material 57 is disposed on the upper surface of the mold release material 53 and the upper surface of the first raw material 55. The second raw material 57 contains copper powder. In the present embodiment, the second raw material 57 does not contain diamond. The second raw material 57 is disposed on the upper surface 51 and on the first raw material 55. FIG. 9B is an enlarged cross-sectional view of a part of FIG. 9A. As illustrated in FIG. 9B, a weight 58 is placed on the second raw material 57, and the first raw material 55 and the second raw material 57 are pressurized at a 10 MPa or more and a 50 MPa or less. At this time, a part of the second raw material 57 enters the inside of each of the recesses 52. Thus, the first raw material 55 and the second raw material 57 are disposed inside the recess 52, and the thickness of the first raw material 55 disposed inside the recess 52 is greater than the thickness of the second raw material 57 disposed inside the recess 52. That is, the proportion of the first raw material 55 is higher than the proportion of the second raw material 57 inside the recess 52.

The mean particle diameter of the copper powder of the first raw material 55 and the mean particle diameter of the copper powder of the second raw material 57 are preferably 1 μm or greater and 8 μm or less. When the mean particle diameter of the copper powder is less than 1 μm, the proportion of the surface area of the copper powder increases. The surface of the copper powder is easily oxidized. Therefore, in a case in which the surface of the copper powder is oxidized, the area of the copper oxide also increases, and thus there is a possibility that the sinterability decreases. When the mean particle diameter of the copper powder exceeds 8 μm, the copper powder is too large to densely cover the surface of the diamond D, and the density and thermal conductivity of the sintered body may be reduced. Thus, the mean particle diameter of the copper powder is preferably 1 μm or greater and 8 μm or less.

In this state, the first raw material 55 and the second raw material 57 are sintered while applying a pressure of 30 MPa or more and 90 MPa or less. For example, the sintering temperature is set to 600° C. or more and 750° C. or less. The copper powder contained in the first raw material 55 and the second raw material 57 is sintered to obtain a sintered body 60 illustrated in FIG. 9C. The sintered body 60 is removed from the jig 50. The sintered body 60 includes a base portion 61 having a flat plate shape and a plurality of protrusions 62 disposed on the base portion 61. The size and shape of the protrusion 62 correspond to the size and shape of the recess 52. In the present embodiment, the protrusions 62 each have a rectangular shape in a plan view and a three-dimensional shape of a rectangular parallelepiped.

As illustrated in FIG. 9B, the first raw material 55 and the second raw material 57 are preferably sintered while being pressurized. This makes it possible to improve the density and thermal conductivity of the sintered body 60 to be fabricated.

In the sintered body 60 of the present embodiment, the base portion 61 contains copper as a main component. A region 62a of the protrusion 62 contains copper and diamond. A region 62b of the protrusion 62 contains copper as a main component. The region 62b is located between the base portion 61 and the region 62a. The region 62a is formed by sintering the first raw material 55. The base portion 61 and the region 62b are formed by sintering the second raw material 57. Therefore, in the sintered body 60 of the present embodiment, the base portion 61 and the region 62b do not contain diamond.

The difference between the area occupied by diamond per unit area of the first portion 11a and that of the second portion 11b of the substrate 1 results from the fact that the second raw material 57 is pressed toward the first raw material 55 as illustrated in FIG. 9B. When the pressure is applied to the second raw material 57, a part of the second raw material 57 enters the recess 52 of the jig 50. A part of the second raw material 57 is mixed with a part of the first raw material 55. The first raw material 55 contains diamond, but the second raw material 57 does not contain diamond. Therefore, the density of diamond is lower in the portion where the first raw material 55 and the second raw material 57 are mixed than that in the portion where such raw materials are not mixed. By sintering the first raw material 55 and the second raw material 57 in this state, the first portion 11a and the second portion 11b of the substrate 1 are formed.

Subsequently, the step of disposing a ceramic member is performed. In the step of disposing a ceramic member, a ceramic member is disposed on the lateral surfaces of each of the plurality of protrusions 62 of the sintered body 60 removed from the jig 50 via an active metal brazing material.

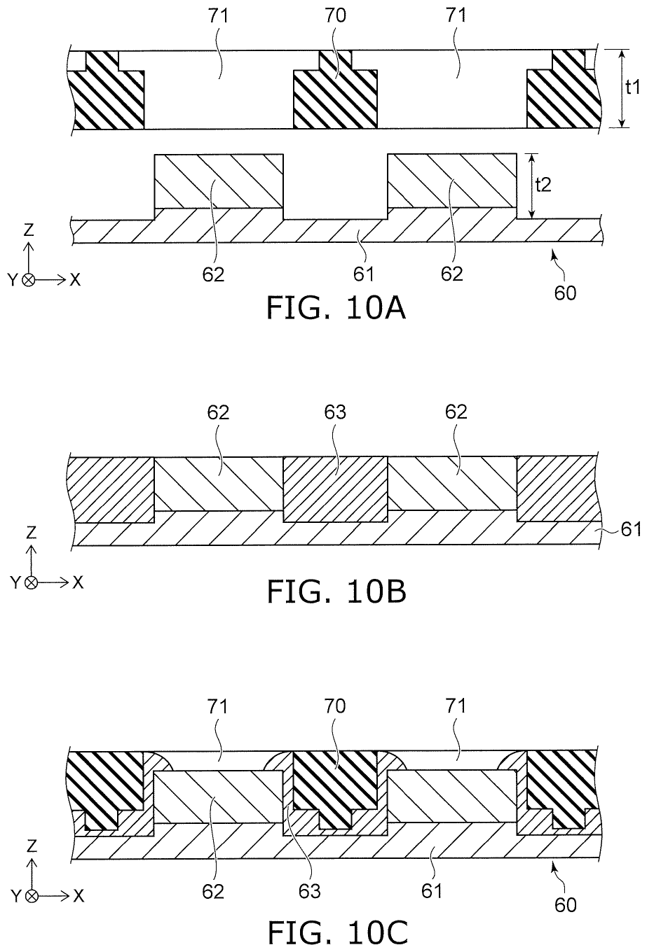

As illustrated in FIG. 10A, a ceramic member 70 having holes 71 is prepared. In a plan view, the outer shape of the protrusion 62 of the sintered body 60 is similar to the outer shape of the hole 71. The ceramic member 70 has a plurality of holes 71 penetrating from the upper surface to the lower surface. The position and size of the hole 71 corresponds to the position and size of the protrusion 62. In the present embodiment, a thickness t1 (the size in the Z direction) of the ceramic member 70 is greater than a thickness t2 of the protrusion 62.

As illustrated in FIG. 10B, an active metal brazing material 63 is adhered to the periphery of the protrusions 62 by printing so as to be flush with the upper surfaces of the protrusions 62. The active metal brazing material only needs to be disposed around the protrusions 62, and can be adhered by syringe filling. At this time, the active metal brazing material 63 can be adhered to the upper surfaces of the protrusions 62. The active metal brazing material 63 contains copper and an active metal element. The active metal element is at least one selected from the group consisting of titanium, hafnium, zirconium, niobium, cerium, and magnesium. The active metal brazing material 63 can further contain silver, tin, indium, or the like. In particular, since the melting point of the active metal brazing material 63 is lowered when the active metal brazing material 63 contains silver, the sintering temperature can be lowered in the step of bonding the ceramic member and the sintered body to be described below.

As illustrated in FIG. 10C, the protrusions 62 of the sintered body 60 having the active metal brazing material 63 adhered to the lateral surface of each thereof are inserted into the corresponding holes 71 of the ceramic member 70. In the present embodiment, the outer peripheral surface of the protrusion 62 and the inner peripheral surface of the hole 71 are spaced apart from each other to such an extent that the active metal brazing material 63 can be disposed between the protrusion 62 and the hole 71. Thus, the ceramic member 70 is disposed on the lateral surface of each of the plurality of protrusions 62 via the active metal brazing material 63. The active metal brazing material 63 is also disposed between the upper surface of the base portion 61 and the lower surface of the ceramic member 70.

Subsequently, the step of bonding the ceramic member 70 and the sintered body 60 is performed by sintering the active metal brazing material 63.

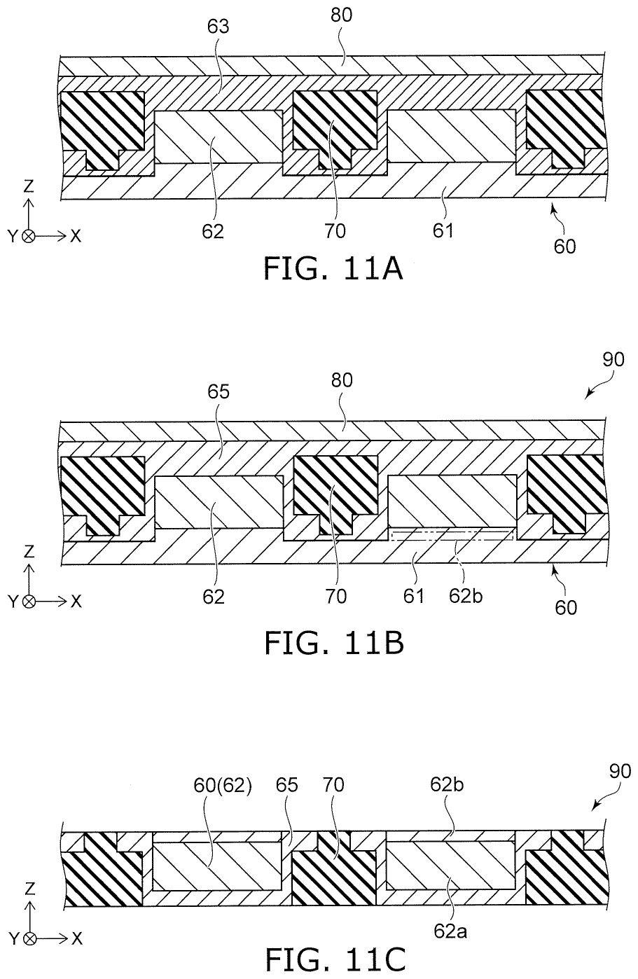

In the step of bonding the ceramic member and the sintered body, as illustrated in FIG. 11A, an active metal brazing material 63 is further adhered onto the protrusions 62 and the ceramic member 70 by printing, and a copper plate 80 is disposed thereon. The size of the copper plate 80 in a plan view is substantially the same as the size of the base portion 61 in a plan view. The copper plate 80 preferably has a thickness equivalent to that of the base portion 61 of the sintered body 60 from the viewpoint of reducing warpage during sintering. The thickness of the copper plate 80 is, for example, 50 μm or greater and 300 μm or less. A layered body composed of the sintered body 60, the active metal brazing material 63, the ceramic member 70, and the copper plate 80 is sintered at a temperature of 700° C. or greater and to 1200° C. or less. At this time, if the diamond D is a composite particle having the diamond particle 41 and a plating layer covering the diamond particle 41, the plating layer can be melted. The melted plating layer becomes a part of the region 62a (the conductive member 10 to be described below) of the protrusion 62.

By the sintering, the active metal brazing material 63 is melted and solidified to form a bonding layer 65 as illustrated in FIG. 11B. The sintered body 60, the ceramic member 70, and the copper plate 80 are bonded to each other by the bonding layer 65 to fabricate a bonded body 90. The step of bonding the ceramic member and the sintered body further includes a step of removing a portion of the sintered body 60 other than the plurality of protrusions 62 after sintering the active metal brazing material 63. As illustrated in FIG. 11C, both surfaces of the bonded body 90 are ground. By grinding both surfaces, the base portion 61 of the sintered body 60, a part of the bonding layer 65, and the copper plate 80 are removed. Of the sintered body 60, only the plurality of protrusions 62 remain. In FIG. 11C, the bonded body 90 is illustrated upside down with respect to FIG. 11B.

In the present embodiment, a part of the sintered body 60 is ground and removed as in the steps illustrated in FIGS. 11B and 11C. At this time, the base portion 61 and a part of the region 62b of the protrusion 62 are ground. In the present embodiment, as illustrated in FIG. 10A, the thickness t1 of the ceramic member 70 fitted to the sintered body 60 is greater than the thickness t2 of the protrusion 62. Therefore, when the copper plate 80 is ground in the subsequent step illustrated in FIG. 11C, the upper surface and the lower surface of the ceramic member 70 serve as stoppers. At this time, the protrusions 62 located on the inner side between the upper surface and the lower surface of the ceramic member 70 in the Z direction are hardly ground. The protrusion 62 at the region 62b has been formed by sintering the second raw material 57 disposed on the first raw material 55 while being pressurized. Since the protrusion 62 does not contain diamond, the protrusion 62 is easily ground. Diamond is harder than copper. Therefore, if a part of the sintered body 60 made of the first raw material 55 is ground, a difference in grinding amount occurs between diamond and copper. As a result, the unevenness of the ground surface increases, reducing flatness. On the other hand, the second raw material 57 does not contain diamond, and therefore can be ground more uniformly. Since diamond is not contained in the region 62b of the protrusion 62, the unevenness of the ground surface of the region 62b can be reduced, improving flatness.

On the opposite side of the base portion 61, a part of the bonding layer 65 adjacent to the protrusion 62 remaining without being ground is a portion to be the third region 13 of the substrate 1. Since the bonding layer 65 does not contain diamond, the bonding layer 65 is easily ground.

The bonded body 90 including the substrate according to the embodiment is fabricated through the steps up to FIG. 11C. The obtained bonded body 90 can be used as the substrate 1, or a plurality of substrates 1 can be manufactured by dividing the bonded body 90 into individual pieces so as to include at least two sintered bodies 60 (protrusions 62). In the bonded body 90, the sintered body 60 and the bonding layer 65 correspond to the conductive member 10 illustrated in FIG. 1. The region 62a corresponds to the first region 11. The region 62b corresponds to the second region 12. The bonding layer 65 corresponds to the third region 13. The ceramic member 70 corresponds to the ceramic member 20.

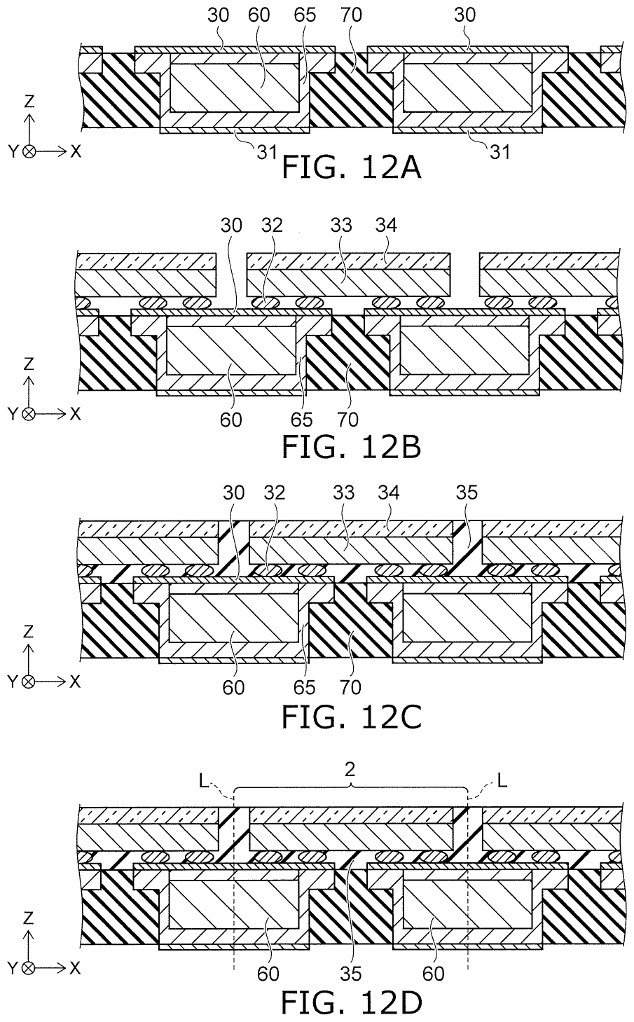

FIGS. 12A to 12C are each a schematic view illustrating a method of manufacturing the light-emitting device according to the embodiment.

The method of manufacturing the light-emitting device 2 includes a step of manufacturing a substrate by the above-described manufacturing method, and a step of disposing one light-emitting element on each of two sintered bodies (corresponding to the protrusions 62 before being removed) among a plurality of sintered bodies (corresponding to the protrusions 62 before being removed) of the substrate.

Hereinafter, a method of manufacturing the light-emitting device 2 in which the bonded body 90 before being divided into individual pieces is used as the substrate will be described. In the present embodiment, the method further includes a step of forming a metal layer on the plurality of protrusions and the ceramic member after the step of disposing a ceramic member. First, electroless plating (displacement plating) is performed on the bonded body 90. As a result, as illustrated in FIG. 12A, a metal layer 30 is formed on the upper surface of the sintered body 60 and the upper surface of the bonding layer 65, and a metal layer 31 is formed on the lower surface of the bonding layer 65. In the present embodiment, since the surface of the sintered body 60 exposed on the upper surface of the bonded body 90 and the lower surface of the bonding layer 65 exposed on the lower surface of the bonded body 90 become the patterns of the metal layer 30 and the metal layer 31, respectively, a mask is not required during electroless plating. Electrolytic plating can be performed with the bonded body 90 provided with wiring lines for supplying power to the surface of the sintered body 60 exposed on the upper surface of the bonded body 90 and the lower surface of the bonding layer 65 exposed on the lower surface of the bonded body 90.

As illustrated in FIG. 12B, light-emitting elements 33 are bonded onto the metal layer 30 via bonding members 32. At this time, one light-emitting element 33 is disposed on two sintered bodies 60 among the plurality of sintered bodies 60 of the bonded body 90 (substrate) such that the positive and negative element electrodes of the light-emitting element 33 are connected to the two sintered bodies 60, respectively. A phosphor member 34 is disposed on each light-emitting element 33. The light-emitting element 33 and the phosphor member 34 can be directly bonded to each other, or can be indirectly bonded to each other with an adhesive member. A white resin is disposed in the gap between the metal layers 30 and the gap between the bonded body 90 and the metal layer 30, and then cured. As a method of molding a white resin, for example, compression molding or transfer molding can be used. When a white resin is provided on the upper surface of the phosphor member 34, the white resin is removed by grinding to expose the phosphor member 34. Thus, as illustrated in FIG. 12C, a covering member 35 covering the lateral surfaces of the light-emitting element 33 and the phosphor member 34 is formed. Alternatively, the covering member 35 can be composed of, for example, a mixture containing boron nitride and alkali metal silicate, instead of the white resin. The mixture can be fabricated by mixing mixed powder of boron nitride powder and silicon oxide powder with an alkaline solution (e.g., potassium hydroxide), followed by heat curing. In the case of potassium hydroxide as the alkaline solution, heat curing causes the silicon oxide and potassium hydroxide to react with each other to form potassium silicate, which is an alkali metal silicate. Boron nitride is a member that can reduce shrinkage of the mixture during heat curing. Aluminum oxide can be used instead of boron nitride.

The present embodiment further includes a step of dividing the substrate 1 into a plurality of pieces such that the light-emitting device 2 includes at least one light-emitting element 33. Specifically, as illustrated in FIG. 12D, the covering member 35 and the bonded body 90 are cut along broken lines L located between the adjacent light-emitting elements 33. The light-emitting device 2 according to the present embodiment is manufactured through the above steps.

### Variations of Substrate 1

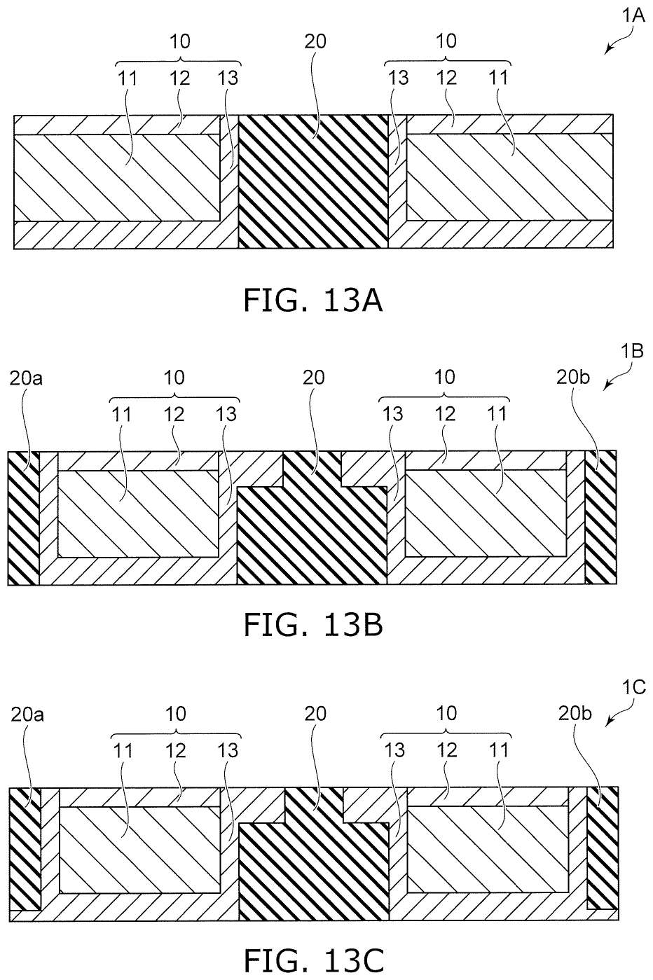

FIGS. 13A to 13C are each a cross-sectional view illustrating a substrate according to a variation of the embodiment. The specific configuration of the substrate according to the embodiment is not limited to the example illustrated in FIGS. 1 to 3. For example, in a substrate 1A illustrated in FIG. 13A, the length of the ceramic member 20 in the X direction is constant over the Z direction. Since it is not necessary to form the ceramic member 20 into a protruding shape in the substrate 1A, the ceramic member 20 can be easily processed, improving productivity. A substrate 1B illustrated in FIG. 13B further includes a ceramic member 20a and a ceramic member 20b, as compared with the substrate 1. The ceramic member 20a and the ceramic member 20b are disposed at both ends of the substrate 1B in the X direction, respectively. The conductive members 10 and the ceramic member 20 are located between the ceramic member 20a and the ceramic member 20b in the X direction. In the substrate 1B, there is no diamond at the cut position when the bonded body 90 is divided into individual pieces, so that the bonded body 90 is easily divided into individual pieces. A substrate 1C illustrated in FIG. 13C differs from the substrate 1B in that the third region 13 is disposed below each of the ceramic members 20a and 20b. In the substrate 1C, there is no diamond at the cut position, as in the substrate 1B, so that the bonded body 90 is easily divided into individual pieces. In addition, with the third region 13 of the conductive member 10 is exposed on the lower surface side of the lateral surface of the substrate 1C, solder creeps up the lateral surface of the substrate 1C to form a fillet when the substrate 1C is mounted on the mounting substrate with solder. Therefore, the heat dissipation of the substrate 1C can be improved.

As illustrated in FIGS. 13A to 13C, the specific configuration of the substrate according to the embodiment can be appropriately changed as long as the first region 11 is provided in the conductive member 10.

The substrate, the light-emitting device, the method of manufacturing a substrate, and the method of manufacturing a light-emitting device of the present disclosure can provide a substrate that can further reduce a difference in thermal expansion coefficient between a conductive member and a ceramic member, and a light-emitting device including the substrate. Therefore, the present disclosure is suitably applicable to a substrate for use in light sources for in-vehicle use, light sources for illumination use, light sources for various indicators, light sources for displays, light sources for liquid crystal display backlights, and light-emitting devices for traffic signals, in-vehicle components, channel letters for signboards, and the like. However, the substrate, the light-emitting device, the method of manufacturing a substrate, and the method of manufacturing a light-emitting device of the present disclosure can be applied to a substrate including a conductive member and a ceramic member for use in various applications.

The above-described embodiment has been presented by way of example embodying the present disclosure, and is not intended to limit the scope of the present disclosure. For example, additions, deletions, or changes of some components or steps in the aforementioned embodiment are also included in the present disclosure. The aforementioned embodiments can be implemented in combination with each other.

What is claimed is:

1. A substrate comprising:
a conductive member comprising
a first region containing copper and diamond,
a second region located on the first region and contains copper as a main component, a first direction being a direction from the first region toward the second region, and
a third region; and
a ceramic member disposed away from the first region and the second region in a second direction perpendicular to the first direction, wherein
the third region is located between the first region and the ceramic member and between the second region and the ceramic member, the third region contains copper and at least one selected from the group consisting of titanium, hafnium, zirconium, niobium, cerium, and magnesium,
the diamond disposed in the first region in a vicinity of the third region is in contact with the third region, and
in a cross section parallel to the first direction, the first region comprises a first portion and a second portion, the second portion is located between the first portion and the second region in the first direction, and an area occupied by the diamond per unit area in the second portion is smaller than an area occupied by the diamond per unit area in the first portion.

2. The substrate according to claim 1, wherein the third region includes a portion located below the first region.

3. The substrate according to claim 1, wherein a particle size of the diamond is 20 μm or greater and 130 μm or less.

4. The substrate according to claim 1, wherein a particle size of the diamond is greater than 20 μm and less than 80 μm.

5. The substrate according to claim 1, wherein in the cross section, the diamond occupies 10% or more and 50% or less of an area of the first region.

6. The substrate according to claim 1, wherein a thickness of the first region in the first direction is greater than a thickness of the second region in the first direction.

7. The substrate according to claim 1, wherein a length of the first region in the second direction and a length of the second region in the second direction are each greater than a length of the ceramic member in the second direction.

8. The substrate according to claim 1, wherein a length of an upper portion of the ceramic member in the second direction is less than a length of a lower portion of the ceramic member in the second direction.

9. The substrate according to claim 1, wherein the third region further contains silver.

10. A light-emitting device comprising:
the substrate according to claim 1; and
a light-emitting element provided on the second region and the ceramic member, the light-emitting element being electrically connected to the second region.

11. A method of manufacturing a substrate, the method comprising:
providing a sintered body having a plurality of protrusions by:
disposing a first raw material inside recesses of a jig, the first raw material containing copper powder and diamond, the jig having an upper surface and the recesses each being recessed from the upper surface,
disposing a second raw material containing copper powder on the first raw material and the upper surface of the jig, and
sintering the first raw material and the second raw material;
disposing, via an active metal brazing material, a ceramic member on at least one lateral surface of each of the plurality of protrusions of the sintered body removed from the jig; and
bonding the ceramic member and the sintered body by sintering the active metal brazing material.

12. The method of manufacturing a substrate according to claim 11, further comprising forming a metal layer on the plurality of protrusions and the ceramic member after the disposing of the ceramic member.

13. The method of manufacturing a substrate according to claim 11, wherein the bonding of the ceramic member and the sintered body further comprises removing a portion of the sintered body other than the plurality of protrusions after the sintering of the active metal brazing material.

14. The method of manufacturing a substrate according to claim 11, wherein a mean particle diameter of the copper powder of the first raw material and a mean particle diameter of the copper powder of the second raw material are 1 μm or greater and 8 μm or less.

15. The method of manufacturing a substrate according to claim 11, wherein a particle size of the diamond is 20 μm or greater and 130 μm or less.

16. The method of manufacturing a substrate according to claim 11, wherein in the providing of the sintered body, the first raw material and the second raw material are sintered while applying a pressure.

17. The method of manufacturing a substrate according to claim 11, wherein a thickness of the first raw material disposed inside each of the recesses is greater than a thickness of the second raw material disposed inside corresponding one of the recesses.

18. The method of manufacturing a substrate according to claim 11, wherein a thickness of the ceramic member is greater than a thickness of each of the plurality of protrusions.

19. A method of manufacturing a light-emitting device, the method comprising:
manufacturing a substrate by the method of manufacturing a substrate according to claim 11; and
disposing one light-emitting element on each of two protrusions among the plurality of protrusions of the sintered body of the substrate.

20. The method of manufacturing a light-emitting device according to claim 19, further comprising dividing the substrate into a plurality of pieces such that at least one light-emitting element is comprised in each of the plurality of pieces.
